(19) United States
(12) Patent Application Publication
(10) Pub. No.: US 2025/0118947 A1
(43) Pub. Date: Apr. 10, 2025

(54) SEMICONDUCTOR LASER ELEMENT

(71) Applicant: NICHIA CORPORATION, Anan-shi (JP)

(72) Inventors: Ryohei HIROSE, Itano-gun (JP); Shingo MASUI, Tokushima-shi (JP); Hisashi OGAWA, Yokohama-shi (JP)

(73) Assignee: NICHIA CORPORATION, Anan-shi (JP)

(21) Appl. No.: 18/910,147

(22) Filed: Oct. 9, 2024

(30) Foreign Application Priority Data
Oct. 10, 2023 (JP) 2023-175306
Sep. 13, 2024 (JP) 2024-159383

(51) Int. Cl. H01S 5/042; H01S 5/12; H01S 5/22

(52) U.S. Cl. CPC H01S 5/04256; H01S 5/12; H01S 5/22

(57) ABSTRACT

A semiconductor laser element includes a semiconductor multilayer portion including an active layer, the semiconductor multilayer portion including (i) a first region including a diffraction grating and (ii) a second region configured to cause laser light to propagate in multiple transverse modes in the second region, the second region including a core region and cladding regions provided on two opposite sides of the core region; at least one electrode disposed on the semiconductor multilayer portion; and a current shielding structure. The semiconductor laser element has a waveguide structure. In a top view, the first region includes a central region where light entering from the second region is propagated and a peripheral region located outward of the central region. In a top view, the current shielding structure is located at a position at least partially overlapping the peripheral region.

### CROSS-REFERENCE TO RELATED APPLICATIONS

This application claims priority to Japanese Patent Application No. 2023-175306, filed on Oct. 10, 2023, and Japanese Patent Application No. 2024-159383, filed on Sep. 13, 2024. The disclosures of these applications are hereby incorporated by reference in their entireties.

### BACKGROUND

### Technical Field

The present disclosure relates to a semiconductor laser element.

### Background Art

In recent years, there has been a demand for higher power in laser light from a semiconductor laser element. A high-power semiconductor laser element has been used, for example, for a light source for processing. For example, Japanese Patent Application Publication No. 2011-151238 discloses a multi-transverse mode laser in which optical damage on the stripe side can be prevented.

### SUMMARY

The semiconductor laser element disclosed in Japanese Patent Application Publication No. 2011-151238 has insufficient power conversion efficiency and has room for improvement.

An object of the present disclosure is to provide a semiconductor laser element having high power conversion efficiency.

A semiconductor laser element according to an embodiment of the present disclosure includes: a semiconductor multilayer portion including an active layer, the semiconductor multilayer portion including (i) a first region including a diffraction grating and (ii) a second region configured to cause laser light to propagate in multiple transverse modes in the second region, the second region including a core region and cladding regions provided on two opposite sides of the core region; at least one electrode disposed on the semiconductor multilayer portion; and a current shielding structure. The semiconductor laser element has a waveguide structure. In a top view, the first region includes a central region where light entering from the second region is propagated and a peripheral region located outward of the central region. In a top view, the current shielding structure is located at a position at least partially overlapping the peripheral region.

As the semiconductor laser element according to an embodiment of the present disclosure, a semiconductor laser element having high power conversion efficiency can be provided.

### BRIEF DESCRIPTION OF DRAWINGS

FIG. 1 is a top view of a semiconductor laser element of a first embodiment according to the present disclosure.

FIG. 2 is a schematic top view of the region structure of the semiconductor laser element according to the first embodiment.

FIG. 3 is a schematic cross-sectional view taken along line III-III of the semiconductor laser element illustrated in FIG. 1.

FIG. 4 is a schematic cross-sectional view taken along line IV-IV of the semiconductor laser element illustrated in FIG. 1.

FIG. 5 is a diagram illustrating an outline of a method of measuring a beam waist radius W₀ and a beam divergence angle φ.

FIG. 6 is a schematic cross-sectional view of a first region of a semiconductor laser element of a second embodiment according to the present disclosure.

FIG. 7 is a schematic cross-sectional view of a first region of a semiconductor laser element of a third embodiment according to the present disclosure.

FIG. 8 is a schematic cross-sectional view of a first region of a semiconductor laser element of a fourth embodiment according to the present disclosure.

FIG. 9 is a schematic top view of another example of the semiconductor laser element of the first embodiment.

### DETAILED DESCRIPTION

Embodiments, modified examples, and examples for implementing the invention according to the present disclosure will be described below with reference to the accompanying drawings. A semiconductor laser element according to the present disclosure described below is intended to embody the technical ideas behind the invention according to the present disclosure, and the invention according to the present disclosure is not limited to the following description unless otherwise specifically stated.

In each drawing, members having identical functions may be denoted by the same reference characters. In consideration of the ease of explanation or understanding of the gist of the invention, the embodiments, modified examples, or examples may be illustrated separately for convenience, but the partial substitutions or combinations of the configurations illustrated in different embodiments, modified examples, and examples are possible. In the embodiments, modified examples, and examples described below, descriptions of matters that are the same as those already described will be omitted, and only different points are described. In particular, similar actions and effects exhibited by similar configurations shall not be mentioned in each embodiment, modified example, and example. The size, positional relationship, and the like of members illustrated in the drawings may be exaggerated in order to clarify explanation.

### First Embodiment

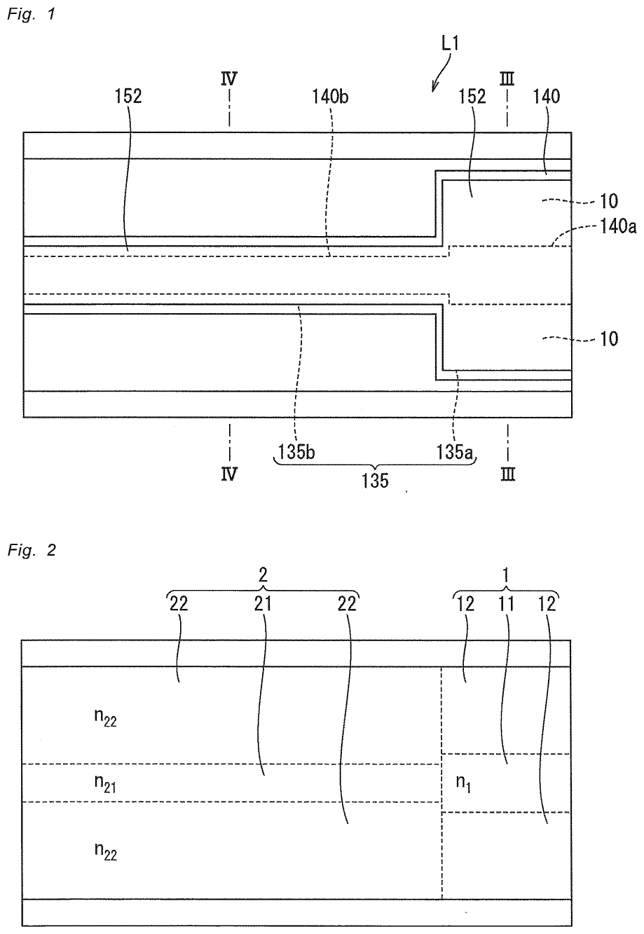

A semiconductor laser element L1 according to the first embodiment includes an active layer 120 and a semiconductor multilayer portion 101 having the waveguide structure illustrated in FIG. 2. FIG. 1 is a schematic top view illustrating the semiconductor laser element L1 of the present embodiment in a top view.

Specifically, as illustrated in FIGS. 1 to 4, the semiconductor multilayer portion 101 of the semiconductor laser element L1 according to the first embodiment includes:
(i) a first region 1 including a diffraction grating 105, and
(ii) a second region 2 including a core region 21 and cladding regions 22 provided on two opposite sides of the core region 21, the second region 2 configured to cause laser light to propagate in multiple transverse modes in the second region 2.

In the semiconductor laser element L1 of the first embodiment, in a top view, the first region 1 includes a central region 11 configured to cause light entered from the second region to propagate in the central region 11, and a peripheral region 12 located outward of the central region 11. A current shielding structure 10 is provided at a position at least partially overlapping the peripheral region 12.

Further, the core region has a refractive index n₂₁, the cladding regions have a refractive index n₂₂, and the central region has a refractive index n₁.

In the semiconductor laser element L1 including the first region 1 and the second region 2 configured as described above, laser light emitted from the second region 2 propagates through the first region 1 at a maximum diffusion angle Θₘₐₓ₁ determined by the refractive indices n₁, n₂₁, and n₂₂.

In the semiconductor laser element L1 according to the first embodiment, the current shielding structure 10 is formed of an insulating film 140 disposed on the semiconductor multilayer portion 101 in the first region 1, as will be described later. For example, the semiconductor laser element L1 is a multi-transverse-mode type semiconductor laser element. When the semiconductor laser element is a multi-transverse-mode semiconductor laser element, the effect of improving light emission efficiency, which is caused by reduction in heat generation due to a reactive current in a portion that does not contribute to oscillation (propagation of light), can be further obtained as compared with a single-transverse-mode semiconductor laser element.

The semiconductor laser element L1 of the first embodiment configured as described above can increase the light emission output with respect to the power consumption and can efficiently obtain high-output light.

The reasons will be described below.

First, in the semiconductor laser element including the diffraction grating 105 in the first region 1 and including the waveguide structure in the second region 2, for example, light emitted by injecting a current into the core region 21 of the second region 2 propagates through the waveguide including the core region 21, is incident on the first region 1, and is then reflected at the diffraction grating 105 in the first region 1 to return to the second region 2, and the returned light is amplified. These are repeated to cause laser oscillation.

In the semiconductor laser element L1 according to the first embodiment, to perform more effective laser oscillation, a coating may be applied to an end surface of the first region 1 on a side opposite to a side on which the second region 2 is located and an end surface of the second region 2 on a side opposite to a side on which the first region 1 is located. The semiconductor laser element L1 may include an anti-reflection coating (AR-coating), provided on the end surface of the first region 1 on the side opposite to the side on which the second region 2 is located, and a high-reflection coating (HR-coating), provided on the end surface of the second region 2 on the side opposite to the side on which the first region 1 is located.

As described above, the laser light incident on the first region 1 including the central region 11 having the refractive index n₁ and emitted from the second region 2 propagates through the first region 1 at the maximum diffusion angle Θₘₐₓ₁ determined by the refractive index n₁, the refractive index n₂₁, and the refractive index n₂₂. In consideration of this, it is preferable to set the width of the region in the first region 1 where the current is injected in the first region 1 to be wider than the width of the region in the second region 2 where the current is injected. This is because the region of the first region 1 where the current is injected functions as the diffraction grating 105. Thus, the light propagating through the first region 1 while spreading at the maximum diffusion angle Θₘₐₓ₁ can be reflected at the diffraction grating 105.

However, the inventors of the present application have found that, although a certain effect of increasing the light-emission efficiency is obtained by setting the width of the region in the first region 1 where the current is injected to be wider than the width of the region in the second region 2 where the current is injected, the light-emission efficiency decreases when the width of the region in the first region 1 where the current is injected is further excessively increased.

In the first region 1, a portion that does not contribute to oscillation (propagation of light) corresponds to a region outside an imaginary line spreading from two opposite ends of the emission end surface of the core region 21 at the maximum diffusion angle Θₘₐₓ₁.

Thus, in the semiconductor laser element according to this embodiment, the current shielding structure 10 is provided in at least a part of the peripheral region 12 including the region outside the imaginary line spreading from two opposite ends of the emission end surface of the core region 21 at the maximum diffusion angle Θₘₐₓ₁ to reduce the reactive current.

In the semiconductor laser element L1 according to the first embodiment, the central region 11 is the region including a region inward of the imaginary lines spreading from two opposite ends of the emission end surface of the core region 21 at the maximum diffusion angle Θₘₐₓ₁. In addition, for example, a region outside the imaginary lines spreading from two opposite ends of the emission end surface of the core region 21 at the maximum diffusion angle Θₘₐₓ₁ can be defined as the peripheral region 12. Furthermore, for example, a region inward of the imaginary lines spreading from two opposite ends of the emission end surface of the core region 21 at the maximum diffusion angle Θₘₐₓ₁ can be defined as the central region 11. By setting the central region 11 to be the region including a region inside the imaginary lines spreading from two opposite ends of the emission end surface of the core region 21 at the maximum diffusion angle Θₘₐₓ₁, it is possible to efficiently inject a current into the region where light propagates, while reducing the reactive current to a region that does not contribute to light propagation.

In this specification, the refractive index n₂₁ and the refractive index n₂₂ refer to effective refractive indices in consideration of optical confinement in the layered direction of the semiconductor multilayer portion 101, and may be referred to as an equivalent refractive index. The refractive index n₁ refers to an effective refractive index for which optical confinement in the layered direction of the semiconductor multilayer portion 101 is considered and variation in the refractive index of the diffraction grating 105 is averaged. The maximum diffusion angle Θₘₐₓ₁ is equal to the maximum light-receiving angle of the optical waveguide in the second region 2.

Hereinafter, the semiconductor laser element L1 according to the first embodiment will be described in detail with reference to the drawings.

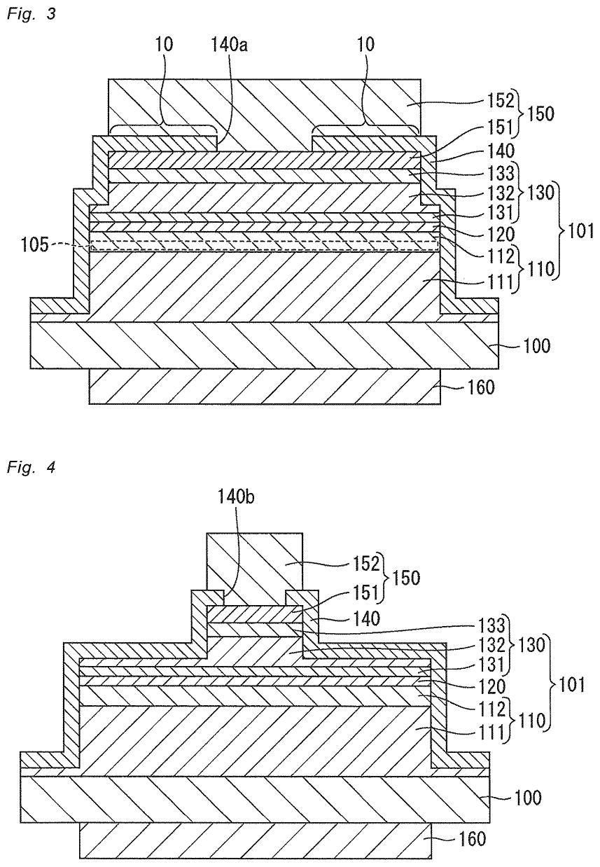

FIG. 1 is a top view of the semiconductor laser element L1 according to the first embodiment. FIG. 2 is a schematic top view of the region structure of the semiconductor laser element L1 according to the first embodiment. FIG. 3 is a schematic cross-sectional view taken along line III-III of the semiconductor laser element L1 illustrated in FIG. 1. FIG. 4 is a schematic cross-sectional view taken along line IV-IV of the semiconductor laser element L1 illustrated in FIG. 1.

The semiconductor laser element L1 according to the first embodiment includes the semiconductor multilayer portion 101 provided on a substrate 100. For example, as illustrated in FIGS. 3 and 4, the semiconductor multilayer portion 101 includes:
(a) an n-side semiconductor layer 110 including an n-side cladding layer 111 and an n-side optical guiding layer 112;
(b) the active layer 120 located on the n-side semiconductor layer 110; and
(c) a p-side semiconductor layer 130 located on the active layer 120 and including a p-side optical guiding layer 131, a p-side cladding layer 132, and a p-side contact layer 133.

The semiconductor multilayer portion 101 includes, for example, a ridge 135 provided in the p-side contact layer 133 and the p-side cladding layer 132. The ridge 135 includes a first ridge 135a provided in the first region 1 and a second ridge 135b provided in the second region 2. In a top view, the first ridge 135a and the second ridge 135b are provided such that, for example, the center lines thereof coincide with each other in the traveling direction of the laser light.

In FIG. 1, the outer lateral surface of the first ridge 135a and the outer lateral surface of the second ridge 135b are illustrated as coinciding with the outer lateral surface of a second electrode 152 described later, and accordingly the first ridge 135a and the second ridge 135b are indicated by dashed lines drawn from the outer lateral surfaces of the first ridge 135a and the second ridge 135b in FIG. 1.

Because the light emitted from the second region 2 and incident on the first region 1 spreads and propagates in the first region 1 as described above, the first ridge 135a is set wider than the second ridge 135b.

Furthermore, the outer lateral surface of the first region 1 and the outer lateral surface of the first ridge 135a are located close to each other, and the refractive index n₁ of the central region 11 is not varied in the light propagation direction and the width direction and is constant in these directions.

In this specification, the width direction refers to a direction orthogonal to both the light propagation direction and the layered direction of the semiconductor multilayer portion 101.

On the semiconductor multilayer portion 101, a p-electrode 150 is disposed in contact with the upper surface of the ridge 135. The p-electrode 150 includes a first electrode 151 and the second electrode 152. The first electrode 151 is disposed in contact with the p-side contact layer 133, the first electrode 151 and the second electrode 152 are connected together via an opening portion of an insulating film, as described later, which shields current. That is, in the first embodiment, the current shielding structure 10 is formed by the insulating film 140 disposed at a position at least partially overlapping the peripheral region 12.

Specifically, first, the first electrode 151 is disposed in contact with, for example, the entire upper surface of the p-side contact layer 133 on the ridge 135 of the semiconductor multilayer portion 101. The insulating film 140 is disposed on the first electrode 151. The insulating film 140 includes a first opening portion 140a located on the first ridge 135a and a second opening portion 140b located on the second ridge 135b. The first opening portion 140a and the second opening portion 140b are, for example, continuous with each other, and for example, the center axes of the first opening portion 140a and the second opening portion 140b coincide with the central lines of the first ridge 135a and the second ridge 135b in the traveling direction of the laser light. In consideration of the fact that the light entering the first region 1 from the second region 2 spreads and propagates in the first region 1, the first opening portion 140a is preferably wider than the second opening portion 140b so that the current injection region in the first region 1 is wider than the current injection region in the second region 2, for example, to increase the light-emission efficiency. However, as described above, if the width of the region in the first region 1 where the current is injected is excessively increased, heat may be generated due to reactive current or the like outside the waveguide region, so that the efficiency may be decreased. In consideration of these, the first opening portion 140a is set to be wider than the second opening portion 140b so that heat generation due to a reactive current or the like outside the waveguide region, in other words, the peripheral region 12, can be effectively reduced. It is preferable that the width of the first opening portion 140a coincides with the imaginary lines spreading from two opposite ends of the emission end surface of the core region 21 at the maximum diffusion angle Θₘₐₓ₁. With this configuration, heat generation due to a reactive current or the like in the peripheral region 12 can be effectively reduced.

In this specification, the term “opening portion” does not only indicate a region surrounded by four sides. For example, a region located between two insulating films can be referred to as an opening portion in the insulating film.

In the first embodiment, the second electrode 152 is disposed to cover the first opening portion 140a and the second opening portion 140b, and the second electrode 152 is connected to the first electrode 151 via the first opening portion 140a and the second opening portion 140b. In other words, the current is injected into the second region 2 via the second opening portion 140b. In the first embodiment, as illustrated in FIG. 4, in the second region 2, the width of the second opening portion 140b is set to be substantially equal to the width of the second ridge 135b. On the other hand, in the first region 1, if the width of the current injection region is excessively increased, there is a possibility of the efficiency being decreased due to heat generation due to a reactive current or the like on the outer side of the waveguide region. Thus, the insulating film 140 is disposed to at least partially overlap the peripheral region 12 to form the current shielding structure 10. Specifically, in the first region 1, the width of the portion where the second electrode 152 and the first electrode 151 are in contact with each other is limited to the width of the first opening portion 140a via the insulating film 140. This structure shields the current in the peripheral region 12. That is, a current is injected from a region where the insulating film 140 is not provided. The first electrode 151 is formed on the entire upper surface of the p-side contact layer 133, for example, and this structure may cause the current injected from the second electrode 152 to spread in the width direction at the first electrode 151 and to be injected into the p-side contact layer 133. Thus, in the first embodiment, the first electrode 151 is preferably configured to reduce the spread of the current in the width direction. For example, in the first embodiment, the first electrode 151 is preferably formed thin to reduce the spread of the current in the width direction. For example, the thickness of the first electrode 151 in the layered direction of the semiconductor multilayer portion 101 is preferably in a range from 0.05 μm to 2 μm. The first electrode 151 may be made of indium-tin oxide (ITO) to reduce the spread of the current in the width direction. Thus, heat generation due to a reactive current or the like outside the waveguide region can be reduced. As described above, the range in which the current flowing to the p-side contact layer 133 is shielded in the first embodiment is determined by parameters including the width of the first opening portion 140a provided in the insulating film 140, the resistance value and thickness of the first electrode 151, and the like. The current is injected into the second region 2 via the second opening portion 140b, which enables the core region 21 and cladding regions 22 to be provided on both sides of the core region 21 in the second region 2, which allows for oscillating light in multi-transverse-mode corresponding to the width of the second opening portion 140b. In other words, it is preferable to appropriately adjust parameters including the width of the first opening portion 140a provided in the insulating film 140, the resistance and thickness of the first electrode 151, and the like so that heat generation due to a reactive current or the like in the peripheral region 12 can be effectively reduced. For example, the width of the first opening portion 140a is preferably 90% or less and more preferably 40% or less of the width of the first region 1 under the condition that the insulating film 140 does not reach the region inward of the imaginary lines spreading at the maximum diffusion angle Θₘₐₓ₁. With this configuration, it is possible to effectively reduce the reactive current to the peripheral region 12. For example, the resistance value of the first electrode 151 can be set in a range from 300 μΩ to 2600 μΩ.

In the semiconductor laser element L1 according to the first embodiment, the width of the ridge 135 is set as follows so that the laser light propagates in desired multiple transverse modes.

First, the second region 2 includes the core region 21 having the refractive index n₂₁ and the cladding regions 22 having the refractive index n₂₂ located on two opposite sides of the core region 21. In addition, the second ridge 135b is provided in the central portion of the p-side semiconductor layer 130 of the second region 2 at a predetermined interval from both lateral surfaces of the second region 2. Thus, in the second region 2, the core region 21 having the refractive index n₂₁ is formed below the second ridge 135b, and the cladding regions 22 having the refractive index n₂₂ are formed on two opposite sides of the core region 21, thereby forming the waveguide structure of the second region 2. In the semiconductor laser element L1 according to the first embodiment, the width of the core region 21, in other words, the width of the second ridge 135b, is set so that laser light including desired multiple transverse modes propagates. The first electrode 151 is preferably disposed in contact with the upper surface of the second ridge side 135b without being in contact with the upper surface of the p-side cladding layer 132 on two opposite sides of the second ridge side 135b. With such a configuration, it is possible to reduce current flowing through the cladding regions 22.

While the core region 21 is formed and the cladding regions 22 are formed on two opposite sides of the core region 21 in a top view by providing the second ridge 135b in the first embodiment, the core region 21 and the cladding regions 22 may be formed without forming the second ridge 135b, for example, by making the current injection portion of the second region 2 narrower in width than the entire second region 2.

In contrast, the first region 1 is not a region in which the light entering from the second region 2 and propagating while spreading at the maximum diffusion angle Θₘₐₓ₁ is confined in a specific wave guide (core region 21) and propagates. Further, the first ridge 135a is not an essential component in the first region 1 as long as the light incident from the second region 2 can be propagated while spreading at the maximum diffusion angle Θₘₐₓ₁. For example, a portion of the semiconductor multilayer portion 101 excluding the second region 2 may be the first region 1 without forming the first ridge 135a. When the first region 1 includes the first ridge 135a, as illustrated in FIG. 3, for example, two opposite lateral surfaces of the first ridge 135a can be located close to two opposite lateral surfaces of the first region 1. The width of the semiconductor multilayer portion 101 forming the first region 1 and the width of the first ridge 135a when including the first ridge 135a are set so that the equivalent refractive indices with respect to the multiple transverse modes of the laser light incident from the second region 2 to the first region 1 are substantially the same and the maximum diffusion angle Θₘₐₓ₁ of the laser light emitted from the second region 2 and entering the first region 1 is taken into consideration so that the propagated light does not leak from the lateral surfaces of the semiconductor multilayer portion 101.

Specifically, in a cross section perpendicular to the optical axis of the laser light, two opposite end portions of the first region 1 in the direction orthogonal to the layered direction of the semiconductor multilayer portion 101 are located outward of the imaginary lines spreading from two opposite ends of the emission end surface of the core region 21 on the first region 1 side at the maximum diffusion angle Θₘₐₓ₁.

The diffraction grating 105 is located in the first region 1. The diffraction grating 105 is provided so that, for example, two opposite ends of the diffraction grating 105 extend to two opposite end portions of the first region 1.

The cross-sectional shape of the ridge 135 may be a rectangular shape having a constant width as illustrated in FIGS. 3 and 4, or may be, for example, a trapezoidal shape in which the width decreases with increasing distance from the substrate 100, or an inverted trapezoidal shape in which the width increases with increasing distance from the substrate 100.

In the semiconductor laser element L1 according to the first embodiment of the present disclosure configured as described above, the width of the waveguide in the second region 2 is set so as to enable laser oscillation including desired multiple transverse modes, and the current shielding structure 10 is provided in the first region 1.

Thus, in the semiconductor laser of the first embodiment, laser light can be oscillated and propagated in multiple transverse modes, so that it is possible to provide the semiconductor laser element L1 that can achieve high power conversion efficiency.

Hereinafter, components of the semiconductor laser element L1 according to the first embodiment will be described in detail with specific examples.

The semiconductor laser element L1 according to the first embodiment is not limited to the following specific examples, and it is sufficient that it has a basic configuration that can obtain the above-described effects.

### Substrate 100

The substrate 100 of the semiconductor laser element L1 according to the first embodiment is, for example, a semiconductor substrate. The substrate 100 is, for example, a nitride semiconductor substrate such as a GaN substrate. The nitride semiconductor substrate may contain an n-type impurity. An element serving as the n-type impurity may be, for example, O, Si, or Ge. The nitride semiconductor substrate may be used as the substrate 100, and an upper surface thereof may be a+c plane (i.e., a (0001) plane). In the first embodiment, the c plane is not limited to a plane exactly coinciding with the (0001) plane, but encompasses a plane having an off-angle of ±1 degree or less, preferably ±0.03 degrees or less. The semiconductor laser element L1 need not include the substrate 100. As the upper surface of the substrate, an m plane, an a plane, an r plane, or the like may be used.

### Semiconductor Multilayer Portion 101

For example, as described above, the semiconductor multilayer portion 101 may include the n-side semiconductor layer 110 including the n-side cladding layer 111 and the n-side optical guiding layer 112; the active layer 120 located on the n-side semiconductor layer 110; and the p-side semiconductor layer 130 located on the active layer 120 and including the p-side optical guiding layer 131, the p-side cladding layer 132, and the p-side contact layer 133.

The semiconductor layer of the semiconductor multilayer portion 101 is an III-V semiconductor layer. Examples of the group III-V semiconductor layer include a nitride semiconductor layer formed having a composition of In_{α}Al_{β}Ga_{1-α-β}N, (0≤α, 0≤β, α+β≤1).

Examples of the element serving as the n-type impurity used for the nitride semiconductor layer include Si and Ge. Further, examples of an element serving as a p-type impurity include Mg. In this case, the nitride semiconductor layer of each conductive type can be formed.

### n-Side Semiconductor Layer 110

The n-side semiconductor layer 110 includes one or more semiconductor layers each containing an n-type impurity. The n-side semiconductor layer 110 may include, for example, the n-side cladding layer 111 having a refractive index n₁₁₁ and the n-side optical guiding layer 112 having a refractive index n₁₁₂. The n-side semiconductor layer 110 may further include an undoped layer that is intentionally undoped with impurities.

The refractive index n₁₁₁ and the refractive index n₁₁₂ are lower than a refractive index n₁₂₀ of the active layer 120. The refractive index n₁₁₁ and the refractive index n₁₁₂ are different from each other, and, for example, the refractive index n₁₁₁ is smaller than the refractive index n₁₁₂.

The n-side cladding layer 111 is disposed between the active layer 120 and the substrate 100. The n-side cladding layer 111 may be, for example, a nitride semiconductor layer. Examples of the nitride semiconductor include AlGaN and GaN. The film thickness of the n-side cladding layer 111 may be, for example, in a range from 0.45 μm to 3.0 μm. The n-type impurity content may be, for example, in a range from 1×10¹⁷ cm⁻³ to 5×10¹⁸ cm⁻³.

The n-side optical guiding layer 112 is disposed between the active layer 120 and the n-side cladding layer 111. The n-side optical guiding layer 112 may be, for example, a nitride semiconductor layer. Examples of the nitride semiconductor include AlGaN, GaN, and InGaN. The film thickness of the n-side optical guiding layer 112 may be, for example, in a range from 0.05 μm to 0.5 μm. The n-type impurity content may be, for example, in a range from 1×10¹⁷ cm⁻³ to 5×10¹⁸ cm⁻³.

### Active Layer 120

The active layer 120 is disposed on the n-side optical guiding layer 112. The active layer 120 emits light having a wavelength in a range from, for example, 360 nm to 800 nm. The active layer 120 may have a quantum well structure formed of one or more well layers and a plurality of barrier layers. The well layer and the barrier layer may be made of, for example, GaN, InGaN, AlGaN, or AlInGaN. The well layer is made of, for example, AlGaN, GaN, or InGaN, which is a nitride semiconductor having a band gap energy less than that of the barrier layer. The active layer 120 may have a multiple quantum well structure or a single quantum well structure. One or both of the well layer and the barrier layer may contain an impurity.

### p-Side Semiconductor Layer 130

The p-side semiconductor layer 130 includes one or more semiconductor layers each containing a p-type impurity. The p-side semiconductor layer 130 is formed on the active layer 120. The p-side semiconductor layer 130 may include, for example, the p-side optical guiding layer 131 having a refractive index n₁₃₁, the p-side cladding layer 132 having a refractive index n₁₃₂, and the p-side contact layer 133 having a refractive index n₁₃₃ in this order from the substrate 100 side (in other words, from the active layer 120 side). The p-side semiconductor layer 130 may include a layer other than these layers. The p-side semiconductor layer 130 may include an undoped layer that is not intentionally doped with impurities.

The refractive index n₁₃₁, the refractive index n₁₃₂, and the refractive index n₁₃₃ are lower than the refractive index n₁₂₀ of the active layer 120. The refractive index n₁₃₁, the refractive index n₁₃₂, and the refractive index n₁₃₃ may be different from each other. For example, the refractive index n₁₃₁ is higher than the refractive index n₁₃₂.

The p-side optical guiding layer 131 may be, for example, a nitride semiconductor layer. Examples of the nitride semiconductor include AlGaN and GaN. The film thickness of the p-side optical guiding layer 131 may be, for example, in a range from 0.05 μm to 0.25 μm. The p-side optical guiding layer 131 may be, for example, an undoped layer and may contain a p-type impurity at a concentration in a range from 1×10¹⁶ cm⁻³ to 1×10¹⁸ cm⁻³.

The p-side cladding layer 132 may be, for example, a nitride semiconductor layer. Examples of the nitride semiconductor include AlGaN and GaN. The p-side cladding layer 132 may have a single-layer structure or a multilayer structure in which nitride semiconductor layers having different compositions are layered. The p-type impurity content may be in a range from, for example, 1×10¹⁷ cm⁻³ to 1×10²⁰ cm⁻³. The p-side cladding layer 132 is not necessarily provided. In a case in which the p-side cladding layer 132 is not provided, the amount of p-type impurities in the semiconductor multilayer portion 101 can be reduced, and the optical loss in the semiconductor multilayer portion 101 can be reduced.

The p-side contact layer 133 may be, for example, a nitride semiconductor. Examples of the nitride semiconductor include AlGaN and GaN. The p-side contact layer 133 may have a single-layer structure or a multilayer structure in which nitride semiconductor layers having different compositions are layered. The p-type impurity content may be in a range from 1×10¹⁹ cm⁻³ to 1×10²² cm³.

### Waveguide Structure

Hereinafter, the waveguide structure of the semiconductor laser element L1 according to the first embodiment will be described in detail.

In the description below, the waveguide structure of the second region 2 will be described first, and then the waveguide structure of the first region 1 will be described.

The waveguide structure of the second region 2 includes the core region 21 having the refractive index n₂₁ and the cladding regions 22 having the refractive index n₂₂ located on two opposite sides of the core region 21 and is a waveguide for propagating light in multiple transverse modes (in other words, multi-transverse-mode) in the longitudinal direction of the core region 21. The number of transverse modes is determined by the width of the core region 21 and the difference between the refractive index n₂₁ of the core region 21 and the refractive index n₂₂ of the cladding regions 22 located on two opposite sides of the core region 21. In the present specification, the width of the core region 21 refers to a width in a direction perpendicular to the layered direction of the semiconductor multilayer portion 101 in a plane perpendicular to the optical axis of the waveguide. The thickness of the core region 21 refers to a thickness in the layered direction of the semiconductor multilayer portion 101 in a plane perpendicular to the optical axis of the waveguide. While the cladding regions 22 are provided on two opposite sides of the core region 21, the refractive indices of the two cladding regions 22 may be the same or different from each other. When the refractive indices are different, the respective refractive indices are n_{22A} and n_{22B}, and the maximum diffusion angle Θₘₐₓ₁ can be calculated using n_{22A} and n_{22B}.

Hereinafter, the number of transverse modes will be described.

In the following description, for the sake of simplicity, a symmetric three-layer flat waveguide will be described. A number N of transverse modes of light propagating through the core region 21 can be set on the basis of the following Formula 1 by obtaining a standardized frequency V defined by the refractive index n₂₁ of the core region 21, the refractive index n₂₂ of the cladding regions 22, and the width of the core region 21.

$$V \geq N π / 2 \qquad ( Formula 1 )$$

(N is an integer of 1 or more)

In Formula 1, the standardized frequency V is expressed by V=k₀n₂₁a(2Δ)^{1/2}. k₀ is a wave number in a vacuum, a is a half width of the core region 21, and Δ(=(n₂₁²−n₂₂²)/(2n₂₁²)) is a relative refractive index difference.

For example, in Formula 1, N is the mode order of the transverse modes, and when the standardized frequency V is in a range from equal to or greater than π/2 to less than 2π/2 (that is, π), light can be propagated in two modes, a 0 order mode (basic mode) and a first order mode. When the standardized frequency V is equal to or greater than Nπ/2 and less than (N+1)π/2, light can be propagated in the 0 order, first order, second order, . . . , and Nth order, that is, (N+1) modes.

In this manner, the number of transverse modes of light propagating through the second region 2 can be set on the basis of Formula 1. Specifically, it can be set on the basis of the width of the second ridge 135b. For a semiconductor laser element having no ridge structure, it can be similarly set on the basis of the parameters constituting the waveguide.

The number of transverse modes is preferably as large as possible in order to obtain a high power and is, for example, 10 or more, preferably 30 or more, and more preferably 50 or more. Although the number of transverse modes is preferably as large as possible in order to obtain a high power, if it is excessively large, problems such as reduction in light concentration may occur. Thus, the number of transverse modes is, for example, 500 or less, preferably 300 or less, and more preferably 100 or less.

As can be understood from the above description of Formula 1, the number of transverse modes is determined by parameters including the width of the core region 21. In consideration of the number of transverse modes and the heat dissipation described above, the width of the core region 21 is, for example, in a range from 15 μm to 120 μm and more preferably from 45 μm to 100 μm.

### Diffraction Grating 105

As illustrated in FIG. 3, the diffraction grating 105 is provided in the first region 1. The diffraction grating 105 is preferably provided in the entire first region 1. Also, the diffraction grating 105 is not provided in the second region 2. The Bragg wavelength in the diffraction grating is represented by the following Formula 2. Formula 2 indicates that the effective diffraction grating period is the product of the equivalent refractive index and a pitch of the diffraction grating.

$$Bragg wavelength ( {λ}_{B} ) = ( equivalent refractive index ( {n}_{1} ) \times pitch ( P ) of diffraction grating ) \times 2 \qquad ( Formula 2 )$$

The diffraction grating 105 can be formed by alternately (periodically) providing regions having different refractive indices in the light propagation direction. The diffraction grating 105 is, for example, located between two adjacent semiconductor layers. The pitch of the diffraction grating 105 can be appropriately selected in consideration of the wavelength of light emitted from the active layer 120.

The equivalent refractive index n₁ of the diffraction grating 105 is substantially the same for each transverse mode, and thus the Bragg wavelength λ_{B} corresponding to each transverse mode is also substantially the same. Thus, the full width at half maximum of the oscillation wavelength of the laser light emitted from the semiconductor laser element L1 is reduced. For example, the full width at half maximum of the oscillation wavelength of the laser light emitted from the semiconductor laser element L1 is in a range from 0.01 nm to 0.5 nm.

In the first embodiment, the diffraction grating 105 is located, for example, between the n-side optical guiding layer 112 and the n-side cladding layer 111. Specifically, the diffraction grating 105 includes one or more first protrusion portions provided on the surface of the n-side cladding layer 111 and protruding toward the n-side optical guiding layer 112 and one or more second protrusion portions provided on the surface of the n-side optical guiding layer 112 and protruding toward the n-side cladding layer 111 alternately in the light traveling direction.

The pitch (P) in Formula 2 is the sum of the length of one first protrusion portion and the length of one second protrusion portion in the light propagation direction.

In the first embodiment, although the diffraction grating 105 is provided between the n-side optical guiding layer 112 and the n-side cladding layer 111, it may be provided in either the n-side optical guiding layer 112 or the n-side cladding layer 111 or may be provided between the n-side optical guiding layer 112 and the active layer 120. The diffraction grating 105 may be provided on the p-side semiconductor layer 130 side.

### Electrodes

As illustrated in FIGS. 3 and 4, the semiconductor laser element L1 includes the p-electrode 150 and an n-electrode 160.

In a case in which the substrate 100 has conductivity, the n-electrode 160 can be disposed on the lower surface of the substrate 100. In a case in which the substrate 100 has insulating properties, the n-electrode 160 can be formed on an exposed surface of the partially exposed n-side cladding layer 111.

Examples of the material of the p-electrode 150 and the n-electrode 160 include a single-layer film or a multilayer film of a metal such as Ni, Rh, Cr, Au, W, Pt, Ti, and Al, an alloy thereof, conductive oxide including at least one selected from Zn, In, and Sn.

The p-electrode 150 may include a light-transmitting conductive film in contact with the ridge 135 as a first electrode. By selecting a material such that the refractive index of the light-transmitting conductive film is smaller than the refractive index of the active layer 120 and the refractive index of the p-side semiconductor layer 130, the light-transmitting conductive film can be treated as a p-side cladding layer. The light-transmitting conductive film is, for example, ITO (indium-tin oxide), IGZO (indium-gallium-zinc oxide), or the like. The insulating film 140 may be, for example, silicon oxide, aluminum oxide, or aluminum nitride.

### Calculation of Maximum Diffusion Angle Θₘₐₓ₁

In the semiconductor laser element L1 according to the first embodiment, the maximum diffusion angle Θₘₐₓ₁ that is to be referenced when setting the position of the current shielding structure 10 can be determined using the factor M², which is given by the following Formula 3 and is an index indicating the quantity of the laser light. The factor M² is an indicator indicating divergence from an ideal Gaussian beam, and the factor M² is 1 for an ideal Gaussian beam. That is, if the factor M² of the laser light emitted from the semiconductor laser element L1 is found, it is possible to find the degree of spread of the laser light as compared with an ideal Gaussian beam, and thus the maximum diffusion angle Θₘₐₓ₁ can be obtained.

$${M}^{2} = πφ {W}_{0} / λ \qquad ( Formula 3 )$$

W₀ is the beam waist radius, and φ is the beam divergence angle.

λ is the wavelength of laser light in a vacuum.

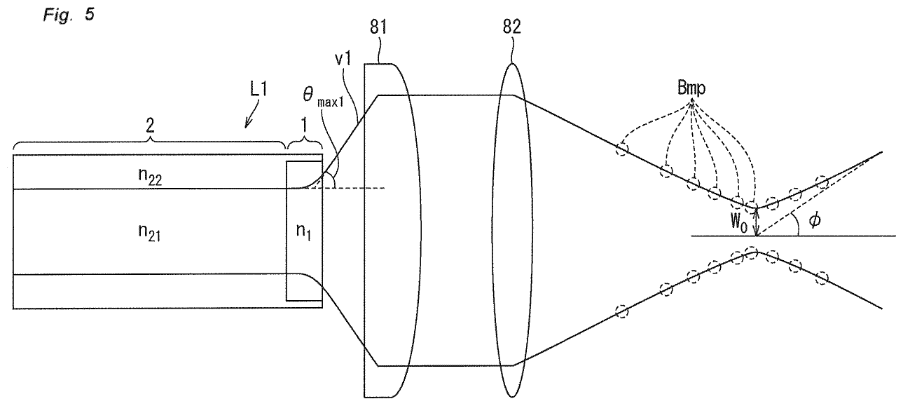

The beam waist radius W₀ and the beam divergence angle φ can be measured in the following manner using an optical system including a collimating lens 81 and a condenser lens 82 illustrated in FIG. 5.

A trajectory of a laser light emitted from the first region 1, collimated by the collimating lens 81, and converged by the condensing lens 82 is traced. Specifically, the beam diameter of the converged laser light is measured at various positions Bmp, the position where the beam diameter is the smallest is estimated, and the beam diameter (beam waist radius W₀) at that position is determined. The divergence of the beam from the position where the beam diameter is the smallest is measured to determine the beam divergence angle φ. The definition of the parameters required for determining the factor M² is based on the International Organization for Standardization ISO 11146-1:2021 or ISO 11146-2:2021. For example, the beam diameter is defined by D4σ (second moment width). The value of the current fed to the semiconductor laser element L1 when measuring the factor M² is within a predetermined operating current range. The factor M² is determined using, for example, a commercially-available measuring device (e.g., THORLABS BP209-VIS/M).

The factor M² is calculated from Formula 3 using the beam waist radius W₀ and the beam divergence angle φ obtained as described above, and the maximum diffusion angle Θₘₐₓ₁ is determined based on the factor M² as described above. The trajectory of the laser light emitted from the second region 2 can be found from the factor M² and the trajectory of the laser light measured in the process of obtaining the factor M². Accordingly, imaginary lines v1 spreading at the maximum diffusion angle Θₘₐₓ₁ from two opposite ends of the emission end surface of the core region 21 are obtained. By comparing the positional relationship between the imaginary line and two opposite ends of the first region 1, the spread of the laser light in the first region 1 can be examined.

As illustrated in FIG. 5 and the like, the maximum diffusion angle Θₘₐₓ₁ is an angle formed by a straight line obtained by removing a curved portion from the imaginary line and a straight line that is an extension of the boundary between the core region 21 and the cladding region 22.

Also, the factor M² of the laser light according to the first embodiment may be in a range from 2 to 100.

When the beam diameter of the laser light at the laser light emission end surface is smaller than the width of the first region 1 and the width of the first region 1 is substantially constant, it is apparent that two opposite end portions of the first region 1 are located outward of the imaginary line v1. Thus, the positional relationship between the width of the first region 1 and the imaginary line v1 can be determined by first measuring the beam diameter of the laser light at the laser light emission end surface.

In the first embodiment, the semiconductor laser element L1 according to the first embodiment has been described using a semiconductor laser element having a ridge structure as an example.

However, the semiconductor laser element L1 according to the first embodiment is not limited to a semiconductor laser element having a ridge structure and may be a rib-waveguide semiconductor laser element or an embedded-heterostructure-waveguide semiconductor laser element.

The semiconductor material constituting the semiconductor laser element described above may be a material other than a nitride semiconductor. The semiconductor material may be, for example, GaAs, InP, GaInP, GaInAsP, GaAlAs, or AlInGaP. In this case, it may be used as a semiconductor laser element having an oscillation wavelength in a range from 760 nm to 1060 nm. A semiconductor laser element made of material other than these materials may also be employed. A semiconductor laser element that emits ultraviolet light may be formed using, for example, aluminum nitride or boron nitride.

The semiconductor laser element described so far may also be expressed as follows. The semiconductor laser element includes, a semiconductor multilayer portion 101 including an active layer 120 and a p-electrode 150 provided on the semiconductor multilayer portion 101, and may include a waveguide structure. The semiconductor multilayer portion 101 includes: (i) a first region 1 including a diffraction grating 105 that is a slab waveguide, and (ii) a second region 2 including a core region 21 and cladding regions 22 provided on two opposite sides of the core region 21.

In a top view, the first region 1 includes a central region 11 configured to cause light entered from the second region to propagate in the central region 11, and a peripheral region 12 located outward of the central region 11. A current shielding structure 10 is provided at a position at least partially overlapping the peripheral region 12. Here, the first region 1 is a slab waveguide. In other words, in the first region 1, a light is confined only in the layered direction. Since the first region 1 where the diffraction grating 105 is provided is a slab waveguide, the equivalent refractive index is almost the same even for different transverse modes, and the selected wavelengths (Bragg wavelengths) in the diffraction grating 105 are aligned. There may be an optical confinement region in the peripheral region 12. Even in that case, the central region 11 of the first region 1 is a slab waveguide.

### Second Embodiment

A semiconductor laser element L2 according to the second embodiment is the same as the semiconductor laser element L1 according to the first embodiment in including the current shielding structure 10 formed of a portion of the insulating film 140, but is different from that in the structure of the p-electrode 150.

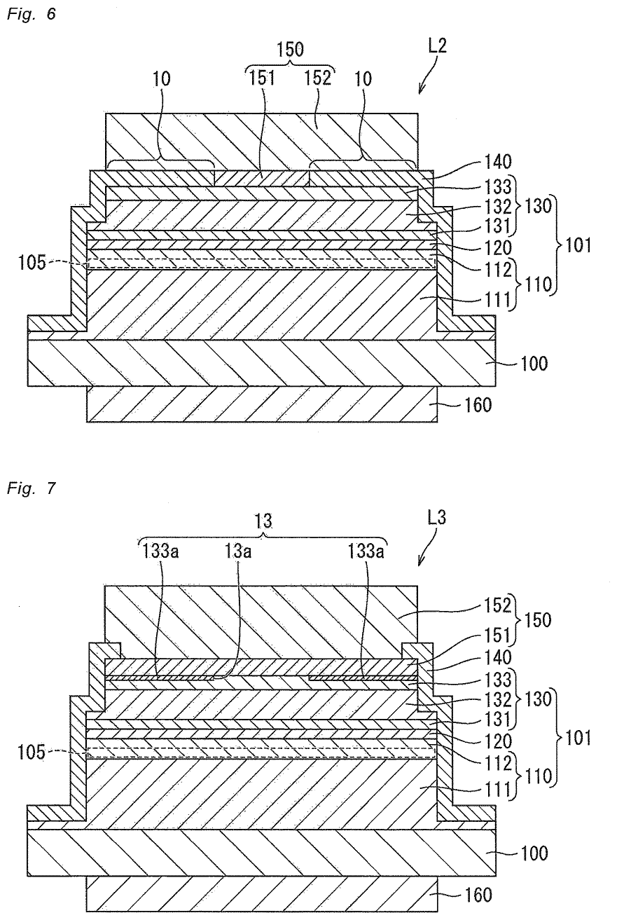

Specifically, in the first region 1 of the semiconductor laser element L2 according to the second embodiment, the first electrode 151 is not disposed to be in contact with the entire upper surface of the p-side contact layer 133 on the ridge 135 of the semiconductor multilayer portion 101. Instead, as illustrated in FIG. 6, the first electrode 151 is disposed inside the first opening portion 140a such that the width of the first electrode 151 is limited to the width of the first opening portion 140a, and the first electrode 151 is in contact with the p-side contact layer 133.

In the semiconductor laser element L2 according to the second embodiment configured as described above, the current in the peripheral region 12 can be shielded, and the reactive current in the peripheral region 12 can be reduced to reduce heat generation.

Thus, according to the semiconductor laser element L2 of the second embodiment, laser light can be oscillated and propagated in multiple transverse modes, and thus it is possible to provide the semiconductor laser element L1 that can achieve high power conversion efficiency.

In the semiconductor laser element L2 according to the second embodiment, the first electrode 151 is disposed inside the first opening portion 140a such that the width of the first electrode 151 is limited to the width of the first opening portion 140a, and the first electrode 151 is in contact with the p-side contact layer 133. This structure can inhibit the current from spreading in the lateral direction in the first electrode 151 and the current can be shielded more effectively.

In the semiconductor laser element L2 according to the second embodiment, the p-electrode 150 in the second region 2 can have any appropriate structure, and may have a structure that is the same as that in the first embodiment, or the first electrode 151 may be disposed inside the second opening portion 140b as in the first region 1.

The semiconductor laser element L2 according to the second embodiment has the same configuration as the semiconductor laser element L1 according to the first embodiment except for the p-electrode 150. For example, the semiconductor laser element L2 is a multi-transverse-mode semiconductor laser element.

### Third Embodiment

A semiconductor laser element L3 according to the third embodiment is different from the semiconductor laser element L1 according to the first embodiment in the configuration of the current shielding structure.

Specifically, as illustrated in FIG. 7, a current shielding structure 13 in the semiconductor laser element L3 according to the third embodiment is made of an oxide film 133a provided on a surface of the semiconductor multilayer portion 101 (a surface of the p-side contact layer 133) and including an opening portion 13a on the central region 11, and is configured such that current is injected from the p-electrode 150 into the central region 11 via the opening portion 13a.

In the semiconductor laser element L3 according to the third embodiment, for example, in the first region 1, the first electrode 151 can be disposed in contact with the entirety of an upper surface of the p-side contact layer 133 on the ridge 135 of the semiconductor multilayer portion 101.

In the semiconductor laser element L3 according to the third embodiment, the oxide film 133a constituting the current shielding structure 13 can be formed by, for example, oxidizing a surface of the p-side contact layer 133. In this manner, the first electrode 151 and the p-side contact layer 133 can be Schottky-joined via the oxide film 133a, and the current shielding structure 13 can be formed.

In the semiconductor laser element L3 according to the third embodiment configured as described above, the current can be shielded in the peripheral region 12, and the reactive current in the peripheral region 12 can be reduced to reduce heat generation.

Thus, according to the semiconductor laser element L3 of the third embodiment, laser light can be oscillated and propagated in multiple transverse modes, and thus it is possible to provide the semiconductor laser element L3 that can achieve high power conversion efficiency.

In the semiconductor laser element L3 according to the third embodiment, the second region 2 can have any appropriate current injection structure, and may have a current injection structure that is the same as or other than that in the first embodiment.

For example, in the second region 2, a second oxide film disposed in the semiconductor multilayer portion 101 and including the second opening portion 140b narrower than the opening portion 13a may be disposed on the waveguide to allow a current to be injected into the second region 2 via the second opening portion 140b. In this manner, in the second region 2, the core region 21 and the cladding regions 22 on two opposite sides thereof can be provided, and light in multi-transverse-mode corresponding to the width of the second opening portion 140b can be oscillated.

In the semiconductor laser element L3 according to the third embodiment, the configuration of the semiconductor multilayer portion 101 and the like other than the current shielding structure 13 is the same as in the semiconductor laser element L1 according to the first embodiment. For example, the semiconductor laser element L3 is a multi-transverse-mode semiconductor laser element.

### Fourth Embodiment

A semiconductor laser element L4 according to the fourth embodiment is different from the semiconductor laser element L1 according to the first embodiment in the configuration of the current shielding structure.

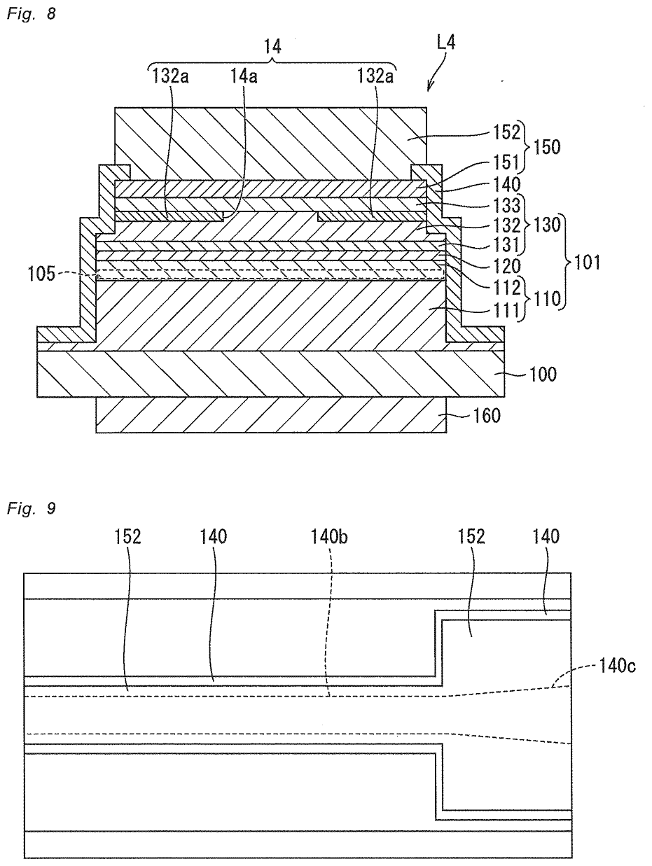

Specifically, as illustrated in FIG. 8, a current shielding structure 14 in the semiconductor laser element L4 according to the fourth embodiment is constituted of a block layer 132a provided in the p-side semiconductor layer 130 of the semiconductor multilayer portion 101 and including an opening portion 14a in the central region 11 to limit current injected from the p-electrode 150 via the opening portion 14a.

In the semiconductor laser element L4 according to the fourth embodiment, for example, in the first region 1, the first electrode 151 can be disposed to be in contact with the entire upper surface of the p-side contact layer 133 on the ridge 135 of the semiconductor multilayer portion 101. The block layer 132a can be provided by forming an undoped layer in a part of the p-side semiconductor layer 130.

While FIG. 8 illustrates an example in which the block layer 132a is provided by making a part of the p-side cladding layer 132 undoped, it is sufficient that the block layer 132a is provided above the active layer 120, in other words, on the p-electrode 150 side. For example, the block layer 132a may be provided in the p-side optical guiding layer 131 or the p-side contact layer 133. In another example, in the p-side semiconductor layer 130, an undoped layer as an additional layer may be provided in addition to the p-side optical guiding layer 131, the p-side cladding layer 132, and the p-side contact layer 133, and the undoped layer can serve as the block layer 132a.

The semiconductor laser element L4 according to the fourth embodiment configured as described above can shield the current in the peripheral region 12 and can reduce the reactive current in the peripheral region 12 to reduce heat generation.

Thus, according to the semiconductor laser element L4 of the fourth embodiment, laser light can be oscillated and propagated in multiple transverse modes, and thus it is possible to provide the semiconductor laser element L4 that can achieve high power conversion efficiency. In the semiconductor laser element L4 according to the fourth embodiment, the second region 2 may have any appropriate current injection structure, and may have a current injection structure that is the same as or other than that in the first embodiment.

For example, in the second region 2, a second block layer provided in the semiconductor multilayer portion 101 and including the second opening portion 140b narrower than the opening portion 14a may be disposed on the waveguide, and a current may be injected into the second region 2 via the second opening portion 140b. In this manner, in the second region 2, the core region 21 and the cladding regions 22 on two opposite sides thereof can be provided, and light in multi-transverse-mode corresponding to the width of the second opening portion 140b can be oscillated.

In the semiconductor laser element L4 according to the fourth embodiment, the configuration of the semiconductor multilayer portion 101 and the like other than the current shielding structure 14 is the same as in the semiconductor laser element L1 according to the first embodiment. For example, the semiconductor laser element L4 is a multi-transverse-mode semiconductor laser element.

### Modified Example

In the above description of the embodiments, for example, in the example of the semiconductor laser element L1 according to the first embodiment described above, the width of the first opening portion 140a provided in the insulating film 140 constituting the current shielding structure 10 is constant.

However, considering that the laser light emitted from the second region 2 propagates through the first region 1 at the maximum diffusion angle Θₘₐₓ₁, the width of the first opening portion 140a does not need to be constant, and the width of the opening portion may increase toward the emission end surface of the first region 1 as illustrated in the first opening portion 140c in FIG. 9. With such a configuration, it is possible to efficiently inject a current into an opening portion and to efficiently reduce the region in which a reactive current flows. For example, it is preferable that the width of the opening portion extends along imaginary lines spreading at the maximum diffusion angle Θₘₐₓ₁.

The same applies to the second to fourth embodiments, and the width of the opening portion may increase toward the emission end surface of the first region 1 for the opening portion 13a formed in the oxide film 133a of the third embodiment and the opening portion 14a formed in the block layer 132a of the fourth embodiment.

### Examples 1 to 3 and Comparative Example 1

The semiconductor laser element L2 was prepared and the output of laser light was measured. To prepare the semiconductor laser element L2, the n-side cladding layer 111, the n-side optical guiding layer 112, the active layer 120, the p-side optical guiding layer 131, the p-side cladding layer 132, and the p-side contact layer 133 are layered on a GaN substrate. The first ridge 135a and the second ridge 135b were obtained by removing a portion from the p-side cladding layer 132 to a part of the p-side optical guiding layer 131. The width of the first ridge 135a was 345 μm, and the width of the second ridge 135b was 90 μm. The diffraction grating 105 was provided in the n-side semiconductor layer 110 in the first region 1, and the period of the diffraction grating 105 was 96 nm. The width of the diffraction grating 105 was 350 μm. The first electrode 151 and the insulating film 140 were layered in this order above the p-side contact layer 133. At this time, the second opening portions 140b were formed to all have the widths of 84 μm, and the first opening portions 140a and the first opening portion 140c of the insulating film 140 were formed to have different shapes. Accordingly, four samples of Examples 1 to 3 and Comparative Example 1 were obtained. The width of the first opening portions 140a and the first opening portion 140c in each example are as illustrated in Table 1. In Example 3, the width of the first opening portion 140c was gradually increased from 90 μm to 101 μm. That is, in Comparative Example 1, the width of the first opening portion 140a is substantially the same as the width of the diffraction grating 105, in Examples 1 and 2, the width of the first opening portion 140a is narrower than that of the sample of Comparative Example 1, and in Example 3, the first opening portion 140a is provided to have a shape spreading along imaginary lines spreading at the maximum diffusion angle Θₘₐₓ₁.

A current was injected into the semiconductor laser elements prepared as per Examples 1 to 3 and Comparative Example 1 to obtain the data illustrated in Table 1.

TABLE 1

| | | Power when | | |
|---|---|---|---|---|
| | Width of first | 6.0 A | Slope | |
| | opening portion | of current is | efficiency | |
| | (μm) | applied (W) | (W/A) | WPE(%) |
| Example 1 | 304 | 8.6 | 1.58 | 30.6 |
| Example 2 | 101 | 9.6 | 1.76 | 33.9 |
| Example 3 | 90-101 | 9.8 | 1.80 | 34.4 |
| Comparative | 342 | 8.3 | 1.51 | 29.1 |
| Example 1 | | | | |

As is apparent from these results, in Examples 1 to 3, the semiconductor laser element obtained had higher power conversion efficiency compared to Comparative Example 1. From the results of Examples 2 and 3, it was found that having the first opening portion 140a with a width coinciding with the imaginary lines spreading from two opposite ends of the emission end surface of the core region 21 at the maximum diffusion angle Θₘₐₓ₁ allows for improving the output, slope efficiency, and WPE of the semiconductor laser element L2.

9.5 A of current was applied to sample (4), the full width at half maximum for the wavelength of the emitted light was measured, and as a result it was 0.15 nm. Although the semiconductor laser element L2 is a multi-transverse-mode semiconductor laser, small wavelength variation was achieved.

Although the embodiment and the modified examples of the present disclosure have been described above, various modifications are possible as long as the configuration based on the technical idea of the present disclosure is included. In addition, various changes can be made to the combination and order of the components in the embodiment and the modified examples within the scope and spirit of the present disclosure.

What is claimed is:

1. A semiconductor laser element, comprising:
a semiconductor multilayer portion comprising an active layer, the semiconductor multilayer portion comprising:
(i) a first region comprising a diffraction grating, and
(ii) a second region configured to cause laser light to propagate in multiple transverse modes in the second region, the second region comprising:
a core region, and
cladding regions located on two opposite sides of the core region;
at least one electrode disposed on the semiconductor multilayer portion; and
a current shielding structure; wherein
the semiconductor laser element has a waveguide structure; and
in a top view, the first region comprises:
a central region where light entering from the second region is propagated, and
a peripheral region located outward of the central region; and
in a top view, the current shielding structure is located at a position at least partially overlapping the peripheral region.

2. The semiconductor laser element according to claim 1, wherein:
the core region has a refractive index n₂₁;
the cladding regions have a refractive index n₂₂;
the central region has a refractive index n₁;
laser light emitted from the second region propagates through the first region at a maximum diffusion angle Θₘₐₓ₁ determined by the refractive index n₁, the refractive index n₂₁, and the refractive index n₂₂; and
the central region comprises a region located inward of imaginary lines spreading from two opposite ends of an emission end surface of the core region at the maximum diffusion angle Θₘₐₓ₁.

3. The semiconductor laser element according to claim 1, wherein:
the current shielding structure comprises an insulating film located on the semiconductor multilayer portion and comprising an opening portion on the central region; and
at least a part of the electrode is located in the opening portion.

4. The semiconductor laser element according to claim 3, wherein:
the at least one electrode comprises a first electrode disposed in the opening portion; and
the first electrode contacts the semiconductor multilayer portion on an inner side of the opening portion.

5. The semiconductor laser element according to claim 3, wherein:
the at least one electrode comprises:
a first electrode disposed on and in contact with the semiconductor multilayer portion, and
a second electrode disposed on the first electrode; and
the second electrode is connected to the first electrode via the opening portion.

6. The semiconductor laser element according to claim 3, wherein a width of the opening portion increases toward an emission end surface of the first region.

7. The semiconductor laser element according to claim 3, wherein:
the second region comprises a second insulating film disposed on the semiconductor multilayer portion and comprising a second opening portion narrower than the opening portion on the second region; and
the electrode is configured to allow a current to be injected into the second region via the second opening portion.

8. The semiconductor laser element according to claim 1, wherein:
the current shielding structure comprises an oxide film provided on a surface of the semiconductor multilayer portion and comprising an opening portion on the central region; and
the electrode is configured to allow a current to be injected into the central region via the opening portion.

9. The semiconductor laser element according to claim 8, wherein the opening portion increases in width toward an emission end surface of the first region.

10. The semiconductor laser element according to claim 8, wherein a width of the opening portion is constant.

11. The semiconductor laser element according to claim 8, wherein:
the second region comprises a second oxide film disposed in the semiconductor multilayer portion and comprising, on the second region, a second opening portion narrower than the opening portion; and
the electrode is configured to allow a current to be injected into the second region via the second opening portion.

12. The semiconductor laser element according to claim 1, wherein:
the current shielding structure comprises a block layer provided in the semiconductor multilayer portion and comprising an opening portion on the central region, and
the electrode is configured to allow a current to be injected into the central region via the opening portion.

13. The semiconductor laser element according to claim 12, wherein a width of the opening portion increases toward an emission end surface of the first region.

14. The semiconductor laser element according to claim 12, wherein a width of the opening portion is constant.

15. The semiconductor laser element according to claim 12, wherein:
the second region comprises a second block layer located in the semiconductor multilayer portion and comprising, on the second region, a second opening portion narrower than the opening portion; and
the electrode is configured to allow a current to be injected into the second region via the second opening portion.

16. A semiconductor laser element, comprising:
a semiconductor multilayer portion comprising an active layer, the semiconductor multilayer portion comprising:
(i) a first region comprising a diffraction grating, the first region being a slab waveguide, and
(ii) a second region comprising:
a core region, and
cladding regions located on two opposite sides of the core region;
at least one electrode disposed on the semiconductor multilayer portion; and
a current shielding structure; wherein
the semiconductor laser element has a waveguide structure; and
in a top view, the first region comprises:
a central region where light entering from the second region is propagated, and
a peripheral region located outward of the central region; and
in a top view, the current shielding structure is located at a position at least partially overlapping the peripheral region.
